(19) United States
(12) Patent Application Publication
(10) Pub. No.: US 2019/0088409 A1
(43) Pub. Date: Mar. 21, 2019

(54) WIRING BOARD AND PLANAR TRANSFORMER

(71) Applicant: NGK SPARK PLUG CO., LTD., Nagoya (JP)

(72) Inventors: Masahito MORITA, Yokohama-shi (JP); Kenji SUZUKI, Ichinomiya-shi (JP)

(21) Appl. No.: 16/127,349

(22) Filed: Sep. 11, 2018

(30) Foreign Application Priority Data
Sep. 15, 2017 (JP) 2017-177557

(51) Int. Cl. H01F 27/32; H01F 27/28; H01F 41/04; H01F 41/12

(52) U.S. Cl. CPC H01F 27/323; H01F 27/2804; H01F 2027/2809; H01F 41/122; H01F 41/041

(57) ABSTRACT

Disclosed is a wiring board having at least one insulating layer and at least one wiring layer arranged to overlap the insulating layer. The insulating layer includes: an arrangement portion at which the wiring layer is arranged; and a side wall portion which surrounds at least a part of the wiring layer arranged at the arrangement portion in a plane direction. The side wall portion has a planar shape that restricts movement and rotation of the wiring layer in the plane direction.

### FIELD OF THE INVENTION

The present invention relates to a wiring board and a planar transformer.

### BACKGROUND OF THE INVENTION

There is known a method for manufacturing a multilayer wiring board in which a plurality of insulating layers and a plurality of wiring layers are alternately laminated together, including a process of forming the wiring layers by printing a metal paste on the insulating layers and firing the printed paste. In this method, however, the wiring layers cannot ensure their sufficient thickness so that there would be a limit to the decrease in resistance of the wiring layers.

On the other hand, there is known a process for forming a wiring layer by bonding a metal foil to an insulating layer (see, for example, Japanese Laid-Open Patent Publication No. H11-329842).

### SUMMARY OF THE INVENTION

In the manufacturing of the wiring board, the wiring layer may be displaced in position relative to the insulating layer during lamination process. Such positional displacement becomes a cause of performance variations in the wiring board. Further, the lamination process becomes complicated when the position of the wiring layer is not fixed during the lamination process. Such complicated lamination process leads to an increase in the manufacturing cost of the wiring board.

In view of the foregoing, it is an object of the present invention to provide a wiring board capable of suppressing positional displacement of a wiring layer relative to an insulating layer. It is also an object of the present invention to provide a planar transformer with such a wiring board.

In accordance with a first aspect of the present invention, there is provided a wiring board, comprising:
at least one insulating layer; and
at least one wiring layer each arranged to overlap any one of the at least one insulating layer,
wherein the at least one insulating layer includes: an arrangement portion at which one of the at least one wiring layer is arranged; and a side wall portion which surrounds at least a part of the one of the at least one wiring layer arranged at the arrangement portion in a plane direction, and
wherein the side wall portion has a planar shape that restricts the one of the at least one wiring layer arranged at the arrangement portion from moving and rotating in the plane direction.

In this configuration, the wiring layer arranged at the arrangement portion of the insulating layer is restricted by the side wall portion of the insulating layer from moving and rotating in the plane direction. It is consequently possible to suppress positional displacement of the wiring layer relative to the insulating layer and thereby possible to facilitate lamination of the wiring layer and the insulating layer and suppress performance variations in the wiring board after the lamination.

In accordance with a second aspect of the present invention, there is provided a wiring board as described above, wherein the side wall portion has at least one of a side wall recess recessed therein in a direction away from the one of the at least one wiring layer arranged at the arrangement portion and a side wall protrusion protruding therefrom in a direction toward the one of the at least one wiring layer arranged at the arrangement portion, and wherein the one of the at least one wiring layer has at least one of a wiring protrusion engaged in the side wall recess and a wiring recess in which the side wall protrusion is engaged.

In this configuration, it is possible to more reliably suppress positional displacement of the wiring layer by at least one of engagement of the side wall recess and the wiring protrusion and engagement of the side wall protrusion and the wiring recess.

In accordance with a third aspect of the present invention, there is provided a wiring board as described above, wherein the side wall portion has, as a combination of two restriction means, a combination of two side wall recesses, a combination of two side wall protrusions and a combination of one side wall recess and one side wall protrusion, and wherein the two restriction means are arranged such that, when viewed in a thickness direction, an imaginary straight line passes through both of the two restriction means and through a geometric center of the gravity of the one of the at least one wiring layer arranged at the arrangement portion.

In this configuration, it is possible to enhance the effect of suppressing rotation of the wiring layer.

In accordance with a fourth aspect of the present invention, there is provided a wiring board as described above, wherein the side wall portion has: two surfaces extending in a first direction, with at least a part of the one of the at least one wiring layer arranged at the arrangement portion being interposed therebetween; and two other surfaces extending in a second direction perpendicular to the first direction, with at least a part of the one of the at least one wiring layer arranged at the arrangement portion being interposed therebetween.

In this configuration, the wiring layer is held from four sides in the plane direction. It is thus possible to more reliably and easily restrict movement and rotation of the wiring layer in the plane direction.

In accordance with a fifth aspect of the present invention, there is provided a wiring board as described above, wherein the side wall portion includes a first region located on one outer side of the arrangement portion in the plane direction and a second region located on the other outer side of the arrangement portion opposite from the first region.

In this configuration, the wiring layer is held between the first and second regions. It is thus possible to suppress movement and rotation of the wiring layer in the plane direction while ensuring the area of the arrangement portion of the insulating layer.

In accordance with a sixth aspect of the present invention, there is provided a wiring board as described above, wherein the at least one wiring layer is not fixed to any of the at least one insulating layer adjacent thereto.

When the wiring layer and the insulating layer expand or contract in accordance with temperature changes, there arises a difference in deformation amount between the wiring layer and the insulating layer due to a difference in thermal expansion coefficient. In this configuration, such a deformation amount difference can be absorbed by individual displacements of the wiring layer and the insulating layer. It is thus possible to reduce stress caused between the insulating layer and the wiring layer and suppress the occurrence of a defect such as crack in the insulating layer.

When the wiring layer is not fixed by adhesion or bonding to the insulating layer, it becomes likely that positional displacement of the wiring layer will occur. It is however possible in the present invention to restrict movement and rotation of the wiring layer relative to the insulating layer as described above. Hence, the wiring layer can be positively placed in a non-adhesion or non-bonding state relative to the insulating layer.

In accordance with a seventh aspect of the present invention, there is provided a wiring board as described above, wherein the at least one insulating layer contains a ceramic material as a main component.

In this configuration, it is possible to improve the flatness of the insulating layer so that the wiring layer can be arranged at high density over the insulating layer. It is also possible to ensure the high insulation properties of the insulating layer.

In accordance with an eighth aspect of the present invention, there is provided a planer transformer comprising the above-described wiring board.

The other objects and features of the present invention will also become understood from the following description.

### BRIEF DESCRIPTION OF DRAWINGS

FIG. 1 is a schematic cross-sectional view of a wiring board, as taken in parallel to a thickness direction thereof, according to a first embodiment of the present invention.

FIG. 2 is a schematic plan view of the wiring board of FIG. 1.

FIG. 3A is a schematic cross-sectional view of a part of the wiring board of FIG. 1 in the vicinity of connection conductors.

FIG. 3B is a schematic cross-sectional view of the wiring board as taken along line IIIB-IIIB of FIG. 3B.

FIG. 4 is a flowchart of a method for manufacturing the wiring board of FIG. 1.

FIG. 5 is a schematic plan view of a wiring board according to a second embodiment of the present invention.

FIG. 6 is a schematic plan view of a wiring board according to a third embodiment of the present invention.

FIG. 7 is a schematic plan view of a wiring board according to a fourth embodiment of the present invention.

### DESCRIPTION OF EMBODIMENTS

Hereinafter, exemplary embodiments of the present invention will be described below with reference to the drawings.

### 1. First Embodiment

[1-1. Structure of Wiring Board]

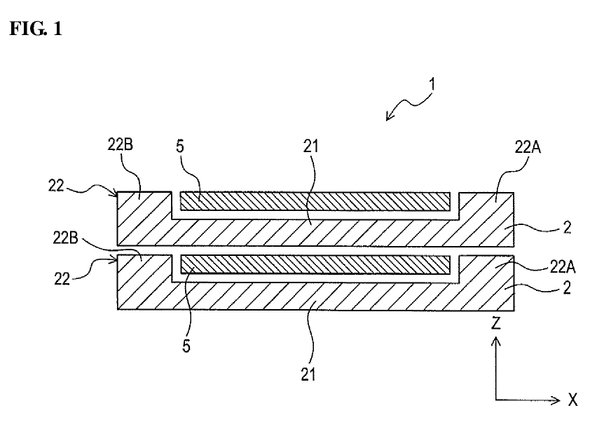

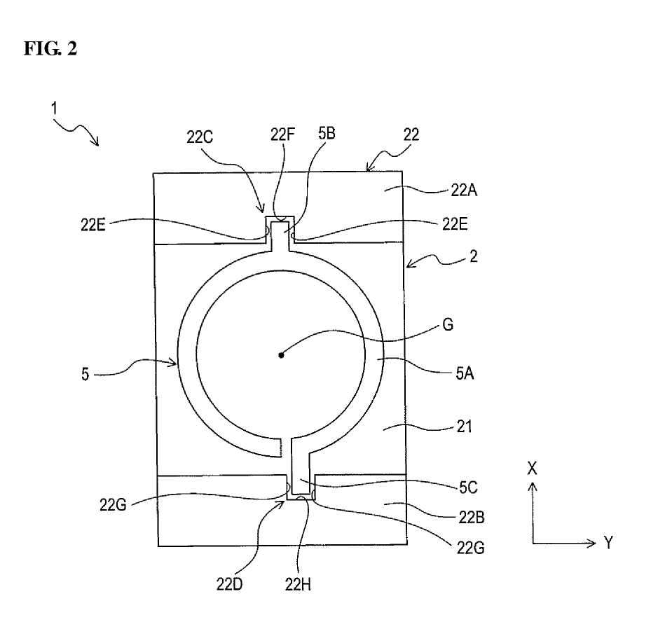

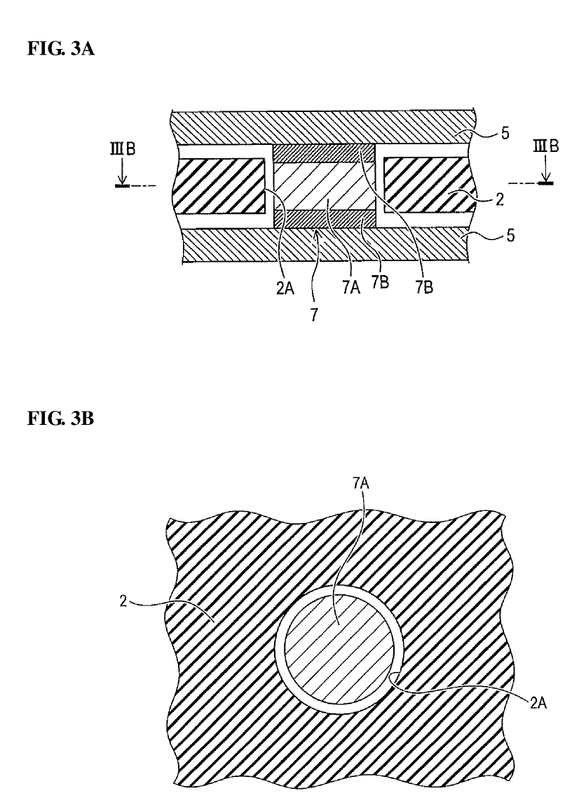

As shown in FIGS. 1 and 2, a wiring board 1 according to a first embodiment of the present invention has a plurality of insulating layers 2, a plurality of wiring layers 5 and at least one connection conductor 7 (see also FIG. 3A) connecting the plurality of wiring layers 5.

Although the wiring board 1 is illustrated as having a multilayer structure with two insulating layers 2 and two wiring layers 5 in the first embodiment, the number of insulating layers 2 and the number of wiring layers 5 are not limited to these numbers. The present invention is applicable to the wiring board 1 as long as the wiring board 1 has at least one insulating layer 2 and at least one wiring layer 5.

Depending on the pattern design of the wiring layers 5, the wiring board 1 can be used for various applications such as a transformer, an insulating gate bipolar transistor (IGBT), a light-emitting diode (LED) illumination device, a power transistor, a motor and the like. The wiring board 1 can particularly suitably be used for high-voltage, high-current applications because of the ease of increasing the thickness of the wiring layers 5.

<Insulating Layers>

Each of the insulating layers 2 has two opposing front and back surfaces and contains a ceramic material as a main component. Herein, the term “main component” refers to a component contained in an amount of 80 mass % or more. Examples of the ceramic material contained in the insulating layers 2 are alumina, beryllia, aluminum nitride, boron nitride, silicon nitride, silicon carbide, LTCC (Low Temperature Co-fired Ceramic) and the like. These ceramic materials can be used solely or in combination of two or more thereof.

As shown in FIG. 1, each of the insulating layers 2 is provided with an arrangement portion 21 and a side wall portion 22.

The arrangement portion 21 is adapted such that one wiring layer 5 is arranged along a surface of the arrangement portion 21. As shown in FIG. 3A, at least one through hole 2A is formed though the arrangement portion 21 in a thickness direction. This through hole 2A is a via hole in which the connection conductor 7 (as a so-called via conductor) is disposed to establish electrical connection between the wiring layers 5 in the thickness direction.

The side wall portion 22 is formed, with a larger thickness than the arrangement portion 21, so as to surround the arrangement portion 21 and at least a part of the wiring layer 5 in a plane direction. In FIG. 2, the wiring layer 5 is not arranged at a position overlapping the side wall portion 22 when viewed in plan. Although not specifically shown in the figures, a relatively small wiring layer (such as electrode), which is less likely to be displaced in position, may be arranged at a position overlapping the side wall portion 22 in plan view.

In the following description, a XYZ coordinate system is used to specify the configurations of the wiring board 1 as shown in FIGS. 1 and 2. As is apparent from these figures, the X and Y directions correspond to the plane direction; and the Z direction corresponds to the thickness direction.

In the first embodiment, the side wall portion 22 includes a first region 22A located on one outer side of the arrangement portion 21 in the X direction and a second region 22A located on the other outer side of the arrangement portion 21 opposite from the first region 22A, as shown in FIG. 2, so as to hold and surround the wiring layer 5 from both sides in the X direction.

More specifically, the first region 22A is formed on one X-direction end part of the front surface of the insulating layer 22; and the second region 22B is formed on the other X-direction end part of the front surface of insulating layer 22. Both of the first and second regions 22A and 22B are elongated rectangular in shape along the Y direction when viewed in the thickness direction (i.e. when viewed in plan). Accordingly, the side wall portion 22 (first and second regions 22A and 22B) surrounds the arrangement portion 21 in the X direction.

The side wall portion 22 has two first and second side wall recesses 22C and 22D formed respectively in the first and second regions 22A and 22B such that each of the side wall recesses 22C and 22D is recessed in a direction away from the wiring layer 5 arranged at the arrangement portion 21.

The first side wall recess 22C formed in the first region 22A has: two first surfaces 22E extending in the X direction and being apart from each other in the Y direction; and a second surface 22F extending in the Y direction and intersecting the two first surfaces 22E at right angles. The two first surfaces 22E are opposed to each other in the Y direction, with the after-mentioned wiring protrusion 5B of the wiring layer 5 being interposed therebetween. Namely, the first side wall recess 22C surrounds one X-direction side (upper side in FIG. 2) of the wiring protrusion 5B and both Y-direction sides (left and right sides in FIG. 2) of the wiring protrusion 5B. It is herein noted that: the X direction corresponds to the claimed first direction; and the Y direction corresponds to the claimed second direction. The same applies to the following.

The second side wall recess 22D formed in the second region 22B has: two third surfaces 22G extending in the X direction and being apart from each other in the Y direction; and a fourth surface 22H extending in the Y direction and intersecting the two third surfaces 22G at right angles. The two third surfaces 22G are opposed to each other in the Y direction, with the after-mentioned wiring protrusion 5C of the wiring layer 5 being interposed therebetween. Further, the fourth surface 22H is opposed to the second surface 22F of the first side wall recess 22C, with the wiring layer 5 being interposed therebetween. Namely, the second side wall recess 22D surrounds one X-direction side (lower side in FIG. 2) of the wiring protrusion 5C and both Y-direction sides (left and right sides in FIG. 2) of the wiring protrusions 5C.

For example, the insulating layer 2 can be formed by providing one insulating layer of constant thickness and arranging another insulating layer on a part of the one insulating layer other than a part corresponding to the arrangement portion 21. The arrangement portion 21 and the side wall portion 22 may alternatively be formed integral with each other.

<Wiring Layers>

Each of the wiring layers 5 has two opposing front and back surfaces. The wiring layers 5 shows electrical conductivity and each contains a metal material as a main component. Examples of the metal material contained in the wiring layers 5 are copper, aluminum, silver, gold, platinum, nickel, titanium, chromium, molybdenum, tungsten, alloys thereof and the like. Among others, copper is preferred in terms of cost, electrical conductivity, thermal conductivity and strength. A copper foil or copper plate (sheet) can suitably be used as the wiring layer 5.

As shown in FIG. 1, the plurality of wiring layers 5 are respectively laminated to the front surfaces of the plurality of insulating layers 2 so that the plurality of insulating layers 2 and the plurality of wiring layers 5 are alternately arranged in the thickness direction. To be more specific, the wiring layers 5 are arranged over the front surfaces of the arrangement portions 21 of the insulating layers 2, respectively.

As shown in FIG. 2, each of the wiring layers 5 is provided with a wiring body portion 5A and two wiring protrusions 5B and 5C.

The wiring body portion 5A mainly functions as electrical wiring. In the first embodiment, the wiring body portion 5A is patterned into a circular coil shape. The shape of the wiring body portions 5A is however not limited to such a coil pattern shape. Even in the case where the wiring body portions 5A has a coil pattern, the coil pattern is not limited to a circular coil pattern.

The two wiring protrusions 5B and 5C are engaged in the side wall recesses 22C and 22D, respectively. The wiring protrusion 5B to be engaged in the side wall recess 22C is formed to extend in the X direction from a middle part of the coil pattern of the wiring body portion 5A. The wiring protrusion 5C to be engaged in the side wall recess 22D is formed to extend in the X direction outwardly from an end part of the coil pattern of the wiring body portion 5A.

The wiring protrusion 5B and the side wall recess 22C are located close to and spaced apart from each other. Similarly, the wiring protrusion 5C and the side wall recess 22D are located close to and spaced apart from each other. The presence of such space is effective to suppress interference of the insulating layer 2 and the wiring layer 5 even when the insulating layer 2 and the wiring layer 5 expand due to temperature changes. The insulating layer 2 and the wiring layer 5 may however be partially in contact with each other within the range not influenced by expansion of the insulating layer 2 and the wiring layer 5.

Further, each of the wiring layers 5 is apart from and is not fixed to any of the insulating layers 2 adjacent thereto in the first embodiment. In other words, each wiring layer 5 does not have a fixed area and have only a non-fixed area assuming that: the fixed area is an area where the wiring layer 5 is fixed to the insulating layers 2 adjacent thereto; and the non-fixed area is an area where the wiring layer 5 is not fixed to the insulating layers 2 adjacent thereto. It is noted that, since the connection conductor 7 is not joined to the corresponding insulating layer 2 as will be explained later in the present embodiment, the junction of the wiring layer 5 to the connection conductor 7 is included in the non-fixed area. Thus, the wiring layers 5 are respectively individually displaceable relative to the insulating layers 2 adjacent thereto.

Alternatively, each of the wring layers 5 may be in contact with any of the insulating layers 2 adjacent thereto as long as the wiring layers 5 are respectively individually displaceable relative to the insulating layers 2 adjacent thereto.

<Positional Relationship of Side Wall Portion and Wiring Layer>

The side wall portion 22 has a planar shape formed with the two side wall recesses 22C and 22D, which respectively surround at least parts of the two wiring protrusions 5B and 5C in the plane direction, to restrict the wiring layer 5 arranged at the arrangement portion 21 from moving and rotating in the plane direction.

When the wiring layer 5 is to be moved in the X direction over the insulating layer 2, the wiring protrusion 5B or 5C of the wiring layer 5 are brought into contact with the second surface 22F of the first side wall recess 22C or the fourth surface 22H of the second side wall recess 22D. By such contact, X-direction movement of the wiring layer 5 is restricted.

When the wiring layer 5 is to be moved in the Y direction over the insulating layer 2, the wiring protrusions 5B and 5C of the wiring layer 5 are respectively brought into contact with one of the two first surfaces 22E of the first side wall recess 22C and one of the two third surface 22G of the second side wall recess 22D. By such contact, Y-direction movement of the wiring layer 5 is restricted.

When the wiring layer 5 is to be rotated in the plane direction over the insulating layer 2, the wiring protrusions 5B and 5C of the wiring layer 5 are respectively brought into contact with one of the two first surfaces 22E of the first side wall recess 22C and one of the two third surface 22G of the second side wall recess 22D. By such contact, rotation of the wiring layer 5 is restricted.

Preferably, the first and second side wall recesses 22C and 22D are in such a positional relationship that, when viewed in plan, there exists an imaginary straight line passing through both of the first and second side wall recesses 22C and 22D and through the geometric center G of gravity of the wiring layer 5. It is particularly preferable that, when the first and second side wall recessed 22C and 22D are brought into contact with the wiring protrusions 5B and 5C to restrict rotation of the wiring layer 5, the positions of contact of the first and second side wall recessed 22C and 22D with the wiring protrusions 5B and 5C are opposed to and face each other via the geometric center G of gravity of the wiring layer 5 in plan view.

<Connection Conductors>

As shown in FIG. 3A, the plurality of connection conductors 7 are respectively disposed in the through holes 2A of the insulating layers 2. Each of the connection conductor 7 serves as a so-called via conductor to electrically connect two wiring layers 5 as mentioned above. The connection conductors 7 are each joined to two wiring layers 5 but are not joined to the corresponding insulating layers 2.

In the first embodiment, each of the connection conductors 7 has a single metal part 7A and junction parts 7B.

The metal part 7A is arranged within the through hole 2A of the insulating layer 2 so as to electrically connect two wiring layers 5 through the junction parts 7B. There is no particular limitation on the material of the metal part 7A. The metal part 7A can be made of the same metal material as that of the wiring layers 5. It is preferable that the material of the metal part 7A is the same as the main component of the wiring layers 5. The use of such a material is effective to reduce stress caused between the connection conductor 7 and the two wiring layers 5 due to temperature changes.

In the first embodiment, the metal part 7A is in the form of a plate-shaped solid block body that is circular when viewed in plan as shown in FIG. 3B. Herein, the term “block body” refers to a column-like body, a plate-like body, a foil-like body or the like. Assuming that the metal part 7A is projected onto an imaginary plane of the insulating layer 2 perpendicular to the thickness direction, the projected area of the metal part 7A is smaller than an opening area of the through hole 2A. Namely, a diameter of the metal part 7A in plan view is smaller than a diameter of the through hole 2A. The planar shape of the metal part 7A is not limited to circular and can alternatively be oval, polygonal or the like.

As shown in FIG. 3A, the metal part 7A is apart from and is not fixed to an inner wall of the through hole 2A of the insulating layer 2 in the first embodiment. Further, a thickness of the metal part 7A is smaller than a depth of the through hole 2A (that is, a thickness of the insulating layer 2 in the vicinity of the through hole 2A).

The junction portions 7B show electrical conductivity to electrically connect the metal part 7A to the two wiring layers 5. As the material of the junction portions 7B, there can be used as a metal brazing material such as silver-copper alloy, a solder material such as tin-silver-copper alloy, or the like.

In one connection conductor 7, the junction parts 7B are disposed so as to cover front and back surfaces of the metal part 7A (facing the two wiring layers 5) as shown in FIG. 3A. More specifically, one of the junction parts 7B is joined to the front surface of the metal part 7A and interposed between the front surface of the metal part 7A and the surface of one of the two wiring layers 5; and the other of the junction parts 7B is joined to the back surface of the metal part 7A and interposed between the back surface of the metal part 7A and the surface of the other of the two wiring layers 5. No junction part 7B is provided on a side surface of the metal part 7A facing the inner wall of the though hole 2A of the insulating layer 2. Furthermore, the junction parts 7B are not joined to the insulating layer 2. There is space left between the connection conductor 7 and the inner wall of the through hole 2A of the insulating layer 2.

It is preferable that, in one connector conductor 7, the volume of the metal part 7A is larger than the total volume of the junction parts 7B.

[1-2. Manufacturing Method of Wiring Board]

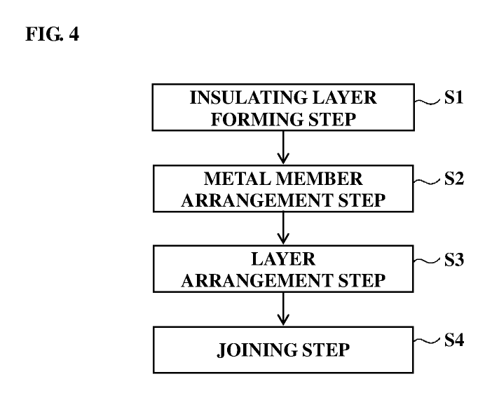

The above-structure wiring board 1 can be manufactured through the following insulating layer forming step S1, metal part arrangement step S2, layer arrangement step S3 and joining step S4 as shown in FIG. 4.

<Insulating Layer Forming Step>

In the insulating layer forming step S1, the plurality of insulating layers 2 are each provided with the arrangement portion 21 and the side wall portion 22; and the through holes 2A are through the insulating layer's 2 in the thickness direction. For example, the insulating layer forming step S1 can be performed as follows. A slurry is first prepared by mixing a powder of ceramic material with an organic binder, a solvent and an additive such as plasticizer. This slurry is formed into a sheet (substrate) shape by a known technique, thereby yielding a plurality of substrate-shaped green ceramic bodies (called “ceramic green sheets”). Each two of the green ceramic sheets are laminated to partially overlap each other, whereby the thus-laminated green ceramic sheet has parts to be processed into the arrangement portion 21 and the side wall portion 22. Then, the through holes 2A are made by e.g. punching through the laminated ceramic green sheets. After that, the laminated ceramic green sheets are fired. As a result, the plurality of ceramic insulating layers 2 are obtained. The plurality of ceramic insulating layers 2 may alternatively be each provided with the arrangement portion 21 and the side wall portion 22 by processing one green ceramic sheet and then subjecting the processed green ceramic sheet to punching and firing.

<Metal Part Arrangement Step>

In the metal part arrangement step S2, the junction parts 7B are laminated on at least parts of the metal parts 7A (more specifically, the front and back surfaces of the metal parts 7A) by the application of metal brazing material or solder material; and then, the metal parts 7A with the junction parts 7B are arranged in the respective through holes 2A of the insulating layers 2.

<Layer Arrangement Step>

In the layer arrangement step S3, the plurality of insulating layers 2 in which the metal parts 7A have been arranged along with the junction parts 7B and the plurality of wiring layers 5 are alternately laminated to one another.

The layer arrangement step S3 may be performed before or in parallel with the metal part arrangement step S2. For example, it is feasible to arrange one wiring layer 5 on the back surface side of one insulating layer 2, arrange the metal part 7A in the though hole 2A of the one insulating layer 2, and then, arrange another wiring layer 5 on the front surface side of the one insulating layer 2.

<Joining Step>

In the joining step S4, each of the metal parts 7A is joined to two of the wiring layers 5 adjacent thereto by heating the laminated layer assembly obtained in the layer arrangement step S3 to thereby melt the junction parts 7B, and then, solidifying the molten material. The connection conductors 7 are formed by this step operation.

[1-3. Effects]

In the first embodiment, the following effects are obtained.

(1a) As mentioned above, the wiring layer 5 arranged at the arrangement portion 21 of the insulating layer 2 is restricted by the side wall portion 22 of the insulating layer 2 from moving and rotating in the plane direction. It is consequently possible to suppress positional displacement of the wiring layer 5 relative to the insulating layer 2 and thereby possible to facilitate lamination of the wiring layer 5 and the insulating layer 2 and suppress performance variations in the wiring board 1 after the lamination.

Especially when the plurality of wiring layers 5 are patterned into a coil shape as mentioned above, it is possible to suppress relative positional displacement of the coil patterns of the wiring layers 5. This prevents a deviation in the overlap of the coil patterns to achieve a reduction in coil pattern diameter.

(1b) In the first embodiment, the side wall portion 22 is provided with two side wall recesses 22C and 22D; and the wiring layer 5 is provided with two wiring protrusions 5B and 5C. It is thus possible to more reliably suppress positional displacement of the wiring layer 5 relative to the insulating layer 2 by engagement of the two wiring protrusions 5B and 5C in the two side wall recesses 22C and 22D.

(1c) Further, the side wall portion 22 has: two surfaces 22E, 22G extending in the X direction, with the wiring layer 5 being interposed therebetween; and two other surfaces 22F and 22H extending in the Y direction, with the wiring layer 5 being interposed therebetween. As the wiring layer 5 is held from four sides in the plane direction, it is possible to more reliably and easily restrict movement and rotation of the wiring layer 5 in the plane direction.

(1d) In the first embodiment, the first and second side wall recesses 22C and 22D are arranged in such a positional relationship that, when viewed in the thickness direction, there exists an imaginary straight line passing through the first and second side wall recesses 22C and 22D and through the geometric center G of gravity of the wiring layer 5. In this arrangement, it is possible to enhance the effect of suppressing rotation of the wiring layer 5.

(1e) As the first and second regions 22A and 22B of the side wall portion 22 are located on opposite sides of the arrangement portion 21, it is possible to suppress movement and rotation of the wiring layer 5 while ensuring the area of the arrangement portion 21.

(1f) Furthermore, each of the wiring layers 5 is not fixed to any of the insulating layers 2 adjacent thereto in the first embodiment. When the wiring layers 5 and the insulating layers 2 expand or contract in accordance with temperature changes, there arises a difference in deformation amount between the wiring layers 5 and the insulating layers 2 due to a difference in thermal expansion coefficient. However, such a deformation amount difference can be absorbed by individual displacements of the wiring layers 5 and the insulating layers 2. It is possible by such displacements to reduce stress caused between the insulating layers 2 and the wiring layers 5 and suppress the occurrence of a defect such as crack in the insulating layers 2.

When the wiring layer 5 is not fixed by adhesion or bonding to the insulating layer 2, it becomes likely that positional displacement of the wiring layer 5 will occur. It is however possible in the first embodiment to restrict movement and rotation of the wiring layer 5 relative to the insulating layer 2 as described above. Hence, the wiring layer 5 can be positively placed in a non-adhesion or non-bonding state relative to the insulating layer 2.

(1g) As the insulating layers 2 contains a ceramic material as a main component, it is possible to improve the flatness of the insulating layers 2 so that the wiring layers 5 can be arranged at high density over the insulating layers 2. It is also possible by the use of such a ceramic material to ensure the high insulation properties of the insulating layer 2 and thereby enable reliable insulation between the wiring layers 5 even in the case where a relatively large current flows though the wiring layers 5.

### 2. Second Embodiment

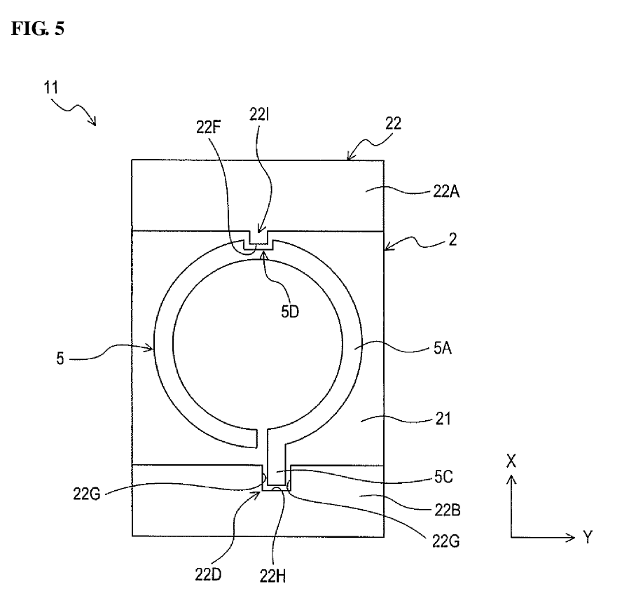

As shown in FIG. 5, a wiring board 11 according to a second embodiment of the present invention has a plurality of insulating layers 2, a plurality of wiring layers 5 and at least one connection conductor 7 (not shown) connecting the plurality of wiring layers 5, as in the case of the wiring board 1 according to the first embodiment. The wiring board 11 according to the second embodiment is structurally the same as the wiring board 1 according to the first embodiment, except for the planar shape of the side wall portions 22 of the insulating layers 2 and the planar shape of the wiring layers 5. An explanation of the configurations of the second embodiment identical or similar to those of the first embodiment will be thus omitted herefrom.

In the second embodiment, the side wall portion 22 has one side wall recess 22D and one side wall protrusion 221 as shown in FIG. 5.

The side wall recess 22D is formed in the second region 22B. This side wall recess 22D is similar to that of FIG. 1. Namely, the side wall recess 22D is situated to allow engagement therein of the after-mentioned wiring protrusion 5C of the wiring layer 5 and has: two third surfaces 22G extending in the X direction and opposed to each other; and a fourth surface 22H extending in the Y direction.

The side wall protrusion 221 is formed on the first region 22A so as to protrude toward the wiring layer 5. The side wall protrusion 221 has, at a tip end part thereof in its protruding direction, a second surface 22F extending in the Y direction. The second surface 22F is opposed to and faces the fourth surface 22H of the side wall recess 22D, with the wiring layer 5 being interposed therebetween.

On the other hand, the wiring layer 5 has a coil-patterned wiring body portion 5A, one wiring protrusion 5C and one wiring recess 5D. The wiring protrusion 5C is similar to that of FIG. 1 and is engaged in the side wall recess 22D. The wiring recess 5D is cut inwardly in a middle part of the coil pattern of the wiring body portion 5A such that the side wall protrusion 221 is engaged in the wiring recess 5D.

Preferably, the side wall recess 22D and the side wall protrusion 221 are in such a positional relationship that, when viewed in plan, there exists an imaginary straight line passing through both of the side wall recess 22D and the side wall protrusion 221 and through the geometric center G of gravity of the wiring layer 5.

As mentioned above, the side wall portion 22 of the wiring board 11 has a planar shape formed with the side wall recess 22D and the side wall protrusion 221 such that the side wall recess 22D surrounds at least a part of the wiring protrusion 5C in the plane direction and such that the wiring recess 5D surrounds at least a part of the side wall protrusion 221 in the plane direction. Consequently, it is possible for the side wall portion 22 to effectively restrict the wiring layer 5 arranged at the arrangement portion 21 from moving and rotating in the plane direction.

### 3. Third Embodiment

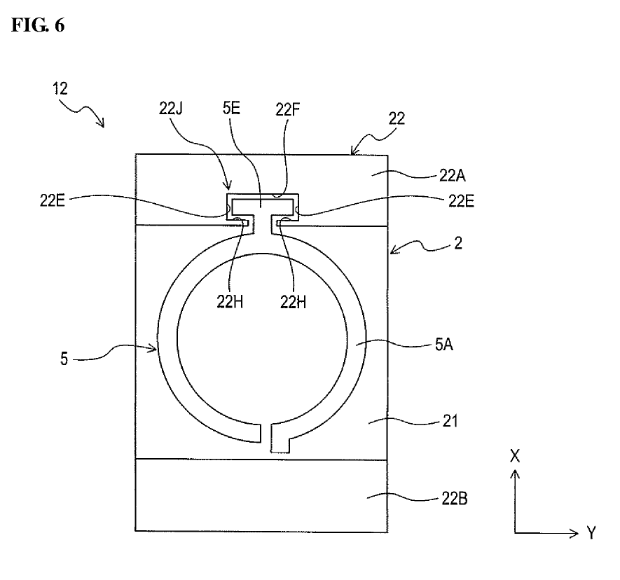

As shown in FIG. 6, a wiring board 12 according to a third embodiment of the present invention has a plurality of insulating layers 2, a plurality of wiring layers 5 and at least one connection conductor 7 (not shown) connecting the plurality of wiring layers 5, as in the case of the wiring board 1 according to the first embodiment. The wiring board 12 according to the third embodiment is structurally the same as the wiring board 1 according to the first embodiment, except for the planar shape of the side wall portions 22 of the insulating layers 2 and the planar shape of the wiring layers 5. An explanation of the configurations of the third embodiment identical or similar to those of the first embodiment will be thus omitted herefrom.

In the third embodiment, the side wall portion 22 has one side wall recess 22J as shown in FIG. 6.

The side wall recess 22J is formed in the first region 22A. The side wall recess 22J has: two first surfaces 22E extending in the X direction and opposed to each other; one second surface 22F extending in the Y direction so as to connect respective one sides of the first surfaces 22E farther away from the wiring layer 5; and two fourth surfaces 22H extending in the Y direction, while being apart from each other in the Y direction, so as to connect the respective other sides of the first surfaces 22E opposite from the second surface 22F. No recess or protrusion is formed on the second region 22B.

The wiring layer 5 has a coil-patterned wiring body portion 5A, and one wiring protrusion 5E. The wiring protrusion 5E is formed to extend in the X-direction outwardly from a middle part of the coil pattern of the wiring body portion 5A. More specifically, the wiring protrusion 5E has a T planar shape, with a tip end part thereof extending to both sides in the Y direction, such that the wiring protrusion 5E is engaged in the side wall recess 22J by being disposed between the two first surfaces 22E of the side surface recess 22J and between the second surface 22F and the two fourth surfaces 2211 of the side surface recess 22J.

As mentioned above, the side wall portion 22 of the wiring board 12 has a planar shape formed with the side wall recess 22J such that the side wall recess 22J surrounds the wiring protrusion 5E from both sides in the X direction and from both sides in the Y direction. Consequently, it is possible for the side wall portion 22 to effectively restrict the wiring layer 5 arranged at the arrangement portion 21 from moving or rotating in the plane direction.

### 4. Fourth Embodiment

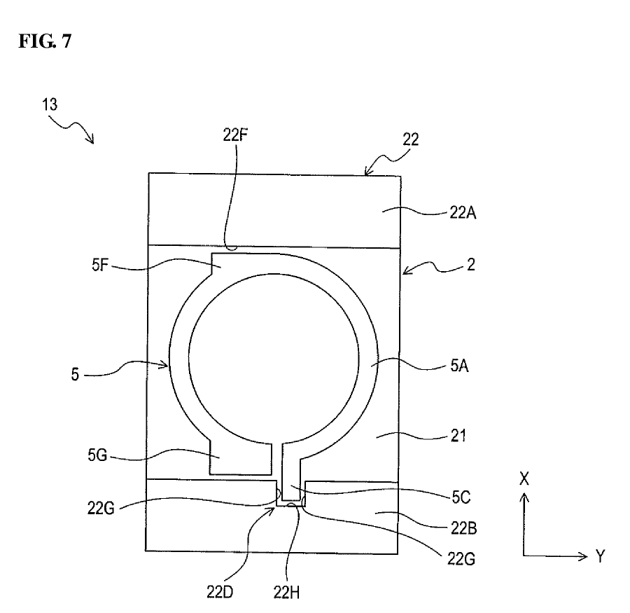

As shown in FIG. 7, a wiring board 13 according to a fourth embodiment of the present invention has a plurality of insulating layers 2, a plurality of wiring layers 5 and at least one connection conductor 7 (not shown) connecting the plurality of wiring layers 5, as in the case of the wiring board 1 according to the first embodiment. The wiring board 13 according to the fourth embodiment is structurally the same as the wiring board 1 according to the first embodiment, except for the planar shape of the side wall portions 22 of the insulating layers 2 and the planar shape of the wiring layers 5. An explanation of the configurations of the fourth embodiment identical or similar to those of the first embodiment will be thus omitted herefrom.

In the fourth embodiment, the side wall portion 22 has one side wall recess 22D as shown in FIG. 7.

The side wall recess 22D is formed in the second region 22B. This side wall recess 22D is similar to that of FIG. 1. Namely, the side wall recess 22D is situated to allow engagement therein of the after-mentioned wiring protrusion 5C of the wiring layer 5 and has: two third surfaces 22G extending in the X direction and opposed to each other; and a fourth surface 22H extending in the Y direction. Although no recess or protrusion is formed on the first region 22A, the first region 22A has a second surface 22F extending in the Y direction and opposed to the wiring layer 5. The second surface 22F is opposed to and faces the fourth surface 2211 of the side wall recess 22D, with the wiring layer 5 being interposed therebetween.

The wiring layer 5 has a coil-patterned wiring body portion 5A, one wiring protrusion 5C and two bulging portions 5F and 5G. The wiring protrusion 5C is similar to that of FIG. 1 and is engaged in the side wall recess 22D. The bulging portions 5F and 5G are formed to bulge outwardly from the coil pattern of the wiring body portion 5A. The bulging portion 5F is situated at a position close to the first region 22A of the side wall portion 22, whereas the bulging portion 5G is situated at a position closed to any part of the second region 22B of the side wall portion 22 other than the side wall recess 22D. When the wiring layer 5 is to be moved or rotated in the X direction over the insulating layer 2, the bulging portions 5F and 5G are respectively brought into contact with the first and second regions 22A and 22B. By such contact, X-direction movement or rotation of the wiring layer 5 is restricted.

As mentioned above, the side wall portion 22 of the wiring board 13 has a planar shape formed with the side wall recess 22D and the first and second regions 22A and 22B such that the side wall recess 22D surrounds at least a part of the wiring protrusion 5C in the plane direction and such that the bulging portions 5F and 5G comes into contact with the first and second regions 22A and 22B. Consequently, it is possible for the side wall portion 22 to effectively restrict the wiring layer 5 arranged at the arrangement portion 21 from moving or rotating in the plane direction.

### 5. Modification Examples

Although the present invention has been described with reference to the above embodiments, the above embodiments are intended to facilitate understanding of the present invention and are not intended to limit the present invention thereto. Various changes and modifications can be made to the above embodiments without departing from the scope of the present invention.

(5a) In the wiring board 1, 11, 12, 13, the side wall portion 22 does not necessarily have first and second regions 22A and 22B, which are formed on opposite sides of the arrangement portion 21, as long as the side wall portion 22 surrounds the wiring layer arrangement portion 21 from at least two different sides in the plane direction. For example, the side wall portion 22 may alternatively have a region extending in the X direction and a region extending in the Y direction. Further, the side wall portion 22 may be formed to surround the entire periphery of the wiring layer 5.

(5b) The side wall portion 22 does not also necessarily have: two surfaces extending in the first direction, with at least a part of the wiring layer 5 being interposed therebetween; and two other surfaces extending in the second direction, with at least a part of the wiring layer 5 being interposed therebetween. That is, the side wall portion 22 does not necessarily have first to fourth surfaces 22E, 22F, 22G and 2211.

(5c) Moreover, the side wall portion 22 does not necessarily have a side wall recess or a side wall protrusion.

(5d) In the wiring board 1, 11, 12, 13, the plurality of wiring layers 5 may be partially or entirely fixed to the insulating layers 2 adjacent thereto by a metal brazing material or solder material. The connection conductors 7 may be fixed to the insulating layers 2. In other words, each of the wiring layers 5 may have two areas: fixed and non-fixed areas and does not necessarily have a non-fixed area.

(5e) The above-mentioned configuration of the connection conductors 7 in the wiring board 1, 11, 12, 13 is merely one example. For example, the metal parts 7A of the connection conductors 7 may be in spherical form. In place of using the metal parts 7A, it is feasible to respectively arrange metal granular bodies in the through holes 2A and join the metal granular bodies to the wiring layers 5 through joint parts. It is alternatively feasible to arrange a metal rod through the plurality of wiring layers 5 in the thickness direction and join the metal rod to the wiring layers 5 through junction parts.

(5f) The material of the insulating layers 2 is not limited to the ceramic material. The insulating layers 2 may each alternatively contain a resin material, glass material or the like as the main component.

(5g) The wiring board 1, 11, 12, 13, in which the plurality of wiring layers 5 have coil wiring patterns at peripheral portions of the adjacent insulating layers 2 as mentioned above, is suitably applicable to a planar transformer. In this case, core insertion holes for insertion of a magnetic core (such as ferrite) may be formed in center portions of the insulating layers 2 so as to pass through the coil wiring patterns.

(5h) In the wiring board 1, 11, 12, 13, the plurality of insulating layers 2 are illustrated as having the same thickness; and the plurality of wiring layers 5 are illustrated as having the same thickness. However, the plurality of insulating layers 2 may be of different thicknesses; and the plurality of wiring layers 5 may be of different thicknesses. Further, the plurality of wiring layers 5 may be of different occupation areas.

(5i) In each of the above embodiments, it is feasible to divide the function of one component among a plurality of components or combine the functions of a plurality of components into one. Any of the technical features of the above embodiments may be omitted, replaced or combined as appropriate. All of embodiments and modifications derived from the technical scope of the following claims are included in the present invention.

The entire contents of Japanese Patent Application No. 2017-177557 (filed on Sep. 15, 2017) are herein incorporated by reference.

What is claimed is:

1. A wiring board, comprising:
at least one insulating layer; and
at least one wiring layer each arranged to overlap any one of the at least one insulating layer,
wherein the at least one insulating layer includes: an arrangement portion at which one of the at least one wiring layer is arranged; and a side wall portion which surrounds at least a part of the one of the at least one wiring layer arranged at the arrangement portion in a plane direction, and
wherein the side wall portion has a planar shape that restricts the one of the at least one wiring layer arranged at the arrangement portion from moving and rotating in the plane direction.

2. The wiring board according to claim 1,
wherein the side wall portion has at least one of a side wall recess recessed therein in a direction away from the one of the at least one wiring layer arranged at the arrangement portion and a side wall protrusion protruding therefrom in a direction toward the one of the at least one wiring layer arranged at the arrangement portion, and
wherein the one of the at least one wiring layer has at least one of a wiring protrusion engaged in the side wall recess and a wiring recess in which the side wall protrusion is engaged.

3. The wiring board according to claim 2,
wherein the side wall portion has, as a combination of two restriction means, a combination of two side wall recesses, a combination of two side wall protrusions and a combination of one side wall recess and one side wall protrusion, and
wherein the two restriction means are arranged such that, when viewed in a thickness direction, an imaginary straight line passes through both of the two restriction means and through a geometric center of the gravity of the one of the at least one wiring layer arranged at the arrangement portion.

4. The wiring board according to claim 2,
wherein the side wall portion has: two surfaces extending in a first direction, with at least a part of the one of the at least one wiring layer arranged at the arrangement portion being interposed therebetween; and two other surfaces extending in a second direction perpendicular to the first direction, with at least a part of the one of the at least one wiring layer arranged at the arrangement portion being interposed therebetween.

5. The wiring board according to claim 1,
wherein the side wall portion includes a first region located on one outer side of the arrangement portion in the plane direction and a second region located on the other outer side of the arrangement portion opposite from the first region.

6. The wiring board according to claim 1,
wherein the at least one wiring layer is not fixed to any of the at least one insulating layer adjacent thereto.

7. The wiring board according to claim 1,
wherein the at least one insulating layer contains a ceramic material as a main component.

8. A planar transformer comprising the wiring board according to claim 1.
